(19) United States
(12) Patent Application Publication
(10) Pub. No.: US 2026/0163584 A1
(43) Pub. Date: Jun. 11, 2026

(54) ANALOG TO DIGITAL CONVERSION DEVICE AND ANALOG TO DIGITAL CONVERSION METHOD

(71) Applicant: REALTEK SEMICONDUCTOR CORPORATION, HSINCHU (TW)

(72) Inventor: WEI-CIAN HONG, Hsinchu (TW)

(21) Appl. No.: 19/413,316

(22) Filed: Dec. 9, 2025

(30) Foreign Application Priority Data
Dec. 10, 2024 (TW) 113147984

(51) Int. Cl. H03M 1/50

(52) U.S. Cl. CPC H03M 1/50

(57) ABSTRACT

An analog to digital conversion device includes a slope signal generator circuit and a comparator circuit. The slope signal generator circuit is configured to generate a slope signal within a first sub-voltage range of a voltage range according to a first current source, and generate the slope signal within a second sub-voltage range of the voltage range according to a second current source, wherein the slope signal repeatedly ramps up and down within the voltage range with at least one slope. The comparator circuit is configured to generate an output signal according to the slope signal and an input signal.

### BACKGROUND OF THE INVENTION

### 1. Field of the Invention

The present disclosure relates to an analog to digital conversion device and an analog to digital conversion method, especially to an analog to digital conversion device and an analog to digital conversion method that can improve nonlinearity of current sources of slope signal generator circuits.

### 2. Description of Related Art

Analog to digital converters (ADCs) are commonly used in electronic devices to convert analog signals into digital signals that can be processed by the electronic devices. A time-interleaved slope ADC is a type of ADC. Slope generators of time-interleaved slope ADCs generally adopt Metal-Oxide-Semiconductor Field-Effect Transistors (MOSFETs) as their current sources. Due to the influence of channel length modulation effect and short channel effects, the current provided by the current source is related to VSD (source-drain voltage). For example, in the case of a current source adopting a PMOS (P-type Metal-Oxide-Semiconductor Field-Effect Transistor), when the slope signal increases, the VSD decreases and the current |IDS| decreases. The formula of the slope signal is as follows:

$$Vslope = I \times \frac{t}{C} \qquad formula 1$$

In Formula 1, Vslope represents the slope signal, I represents the current, t represents time, and C represents the capacitance value. Assuming that the time t and the capacitance value C are fixed, if the current I is not a fixed value but varies with VSD, the slope signal Vslope will not be a charging curve with a fixed slope, thereby introducing a nonlinear component.

### SUMMARY OF THE INVENTION

In some aspects, an object of the present disclosure is to, but not limited to, provides an analog to digital conversion device and an analog to digital conversion method that makes an improvement to the prior art.

An embodiment of an analog to digital conversion device includes a slope signal generator circuit and a comparator circuit. The slope signal generator circuit is configured to generate a slope signal within a first sub-voltage range of a voltage range according to a first current source, and generate the slope signal within a second sub-voltage range of the voltage range according to a second current source, wherein the slope signal repeatedly ramps up and down within the voltage range with at least one slope. The comparator circuit is configured to generate an output signal according to the slope signal and an input signal.

An embodiment of an analog to digital conversion method includes: generating a slope signal within a first sub-voltage range of a voltage range according to a first current source, and generating the slope signal within a second sub-voltage range of the voltage range according to a second current source by a slope signal generator circuit, wherein the slope signal repeatedly ramps up and down within the voltage range with at least one slope; and generating an output signal according to the slope signal and an input signal by a comparator circuit.

Technical features of some embodiments of the present disclosure make an improvement to the prior art. The analog to digital conversion device and the analog to digital conversion method of the present disclosure can improve nonlinearity of current sources of slope signal generator circuits.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of an analog to digital conversion device of the present disclosure.

FIG. 2 shows an embodiment of a flow diagram of an analog to digital conversion method of the present disclosure.

FIG. 3 shows an embodiment of a timing diagram of an analog to digital conversion device of the present disclosure.

FIG. 4 shows an embodiment of a current source of the present disclosure.

FIG. 5 shows an embodiment of current-voltage characteristic diagram of a slope signal generator circuit of the present disclosure.

FIG. 6 shows an embodiment of a current source of the present disclosure.

### DETAILED DESCRIPTION OF THE PREFERRED EMBODIMENTS

To address the issue of nonlinearity of slope signals in the prior art, the present disclosure provides an analog to digital conversion device and an analog to digital conversion method, which will be explained in detail as shown below.

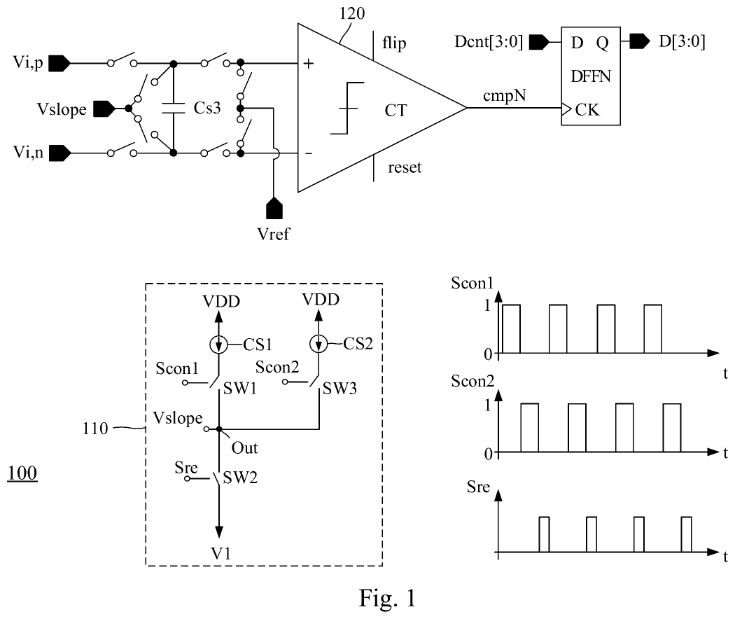

FIG. 1 shows an embodiment of an analog to digital conversion device 100 of the present disclosure. As shown in the figure, the analog to digital conversion device 100 includes a slope signal generator circuit 110, a comparator circuit 120, a capacitor Cs3, and a flip-flop DFFN.

In some embodiments, the analog to digital conversion device 100 may be, but is not limited to, a time-interleaved slope analog to digital converter, and the operation of the analog to digital conversion device 100 is described as follows. The analog to digital conversion device 100 may sample an input signal using the capacitor Cs3. Subsequently, the comparator circuit 120 compares the sampled signal with a slope signal Vslope generated by the slope signal generator circuit 110. Before the comparator circuit 120 generates a comparison result, a counter continues counting a count value Dont [3:0] until the comparator circuit 120 generates the comparison result. When the positive terminal of the comparator circuit 120 becomes greater than the negative terminal, the output signal cmpN generated by the comparator circuit 120 transitions from low to high. The rising edge of the output signal cmpN transitioning from low to high triggers the flip-flop DFFN, and the flip-flop DFFN stores the current counting value Dont [3:0] and subsequently outputs a data signal D [3:0]. As described above, the analog to digital conversion device 100 completes a conversion cycle.

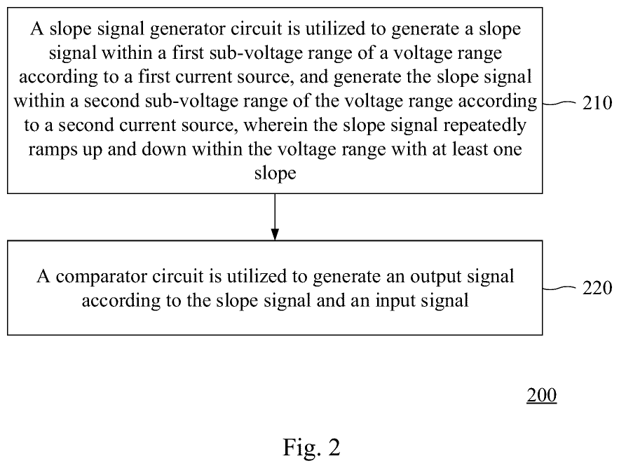

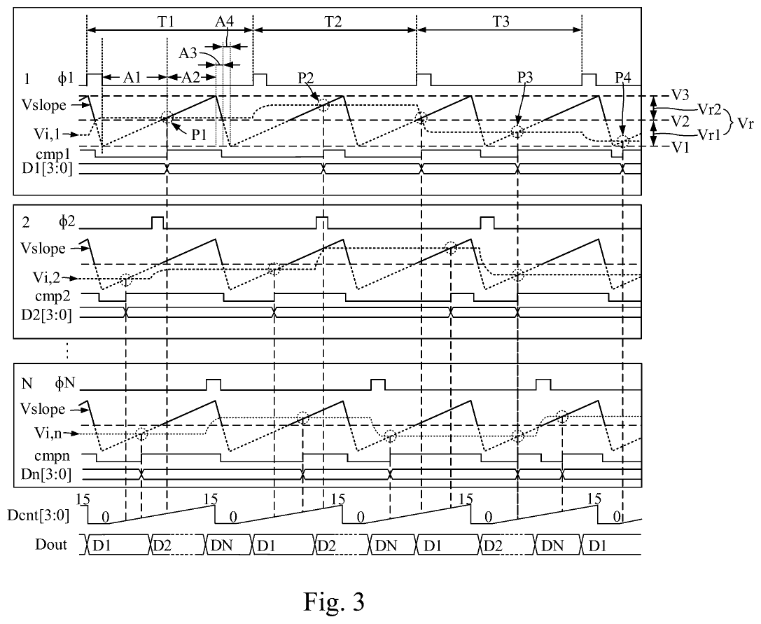

To illustrate how the analog to digital conversion device 100 of the present disclosure improves nonlinearity of the slope signal Vslope, please refer to FIGS. 2 and 3. FIG. 2 shows an embodiment of a flow diagram of an analog to digital conversion method 200 of the present disclosure. FIG. 3 shows an embodiment of the timing diagram of the analog to digital conversion device 100 of the present disclosure.

Referring to step 210 of FIG. 2, a slope signal generator circuit is utilized to generate a slope signal within a first sub-voltage range of a voltage range according to a first current source, and generate the slope signal within a second sub-voltage range of the voltage range according to a second current source, wherein the slope signal repeatedly ramps up and down within the voltage range with at least one slope. For example, referring to FIGS. 1, 3, the slope signal generator circuit 110 generates a slope signal Vslope (as shown in the dotted portion of the slope signal Vslope) within the first sub-voltage range Vr1 of the voltage range Vr according to a first current source CS1, and generates the slope signal Vslope (as shown in the solid portion of the slope signal Vslope) within the second sub-voltage range Vr2 of the voltage range Vr according to a second current source CS2. The slope signal Vslope ramps up with one slope and ramps down with another slope within the voltage range Vr to complete one up-and-down cycle, and the slope signal Vslope repeatedly ramps up and down within the voltage range Vr in a periodic manner.

Referring to step 220 of FIG. 2, a comparator circuit is utilized to generate an output signal according to the slope signal and an input signal. For example, referring to FIGS. 1, 3, using the input signal Vi, 1 as an example, the comparator circuit 120 generates an output signal cmp1 according to the slope signal Vslope and the input signal Vi, 1.

In some embodiments, the voltage range Vr includes a low voltage level V1 and a high voltage level V3, and at least one slope of the slope signal Vslope includes a positive slope and a negative slope. The slope signal Vslope ramps up from the low voltage level V1 to the high voltage level V3 with the positive slope, and then ramps down from the high voltage level V3 to the low voltage level V1 with the negative slope.

In some embodiments, the first sub-voltage range Vr1 includes the low voltage level V1. A boundary between the first sub-voltage range Vr1 and the second sub-voltage range Vr2 includes an intermediate voltage level V2. At least one slope of the slope signal Vslope includes a positive slope and a negative slope. The slope signal Vslope ramps up from the low voltage level V1 to the intermediate voltage level V2 within a first period A1 with the positive slope according to the first current source CS1 (as represented by the dashed portion of the slope signal Vslope).

In some embodiments, the second sub-voltage range Vr2 includes the high voltage level V3. The slope signal Vslope ramps up from the intermediate voltage level V2 to the high voltage level V3 within a second period A2 with the positive slope according to the second current source CS2 (as represented by the solid portion of the slope signal Vslope).

In some embodiments, the slope signal Vslope ramps down from the high voltage level V3 to the intermediate voltage level V2 within a third period A3 with the negative slope according to the second current source CS2 (as represented by the solid portion of the slope signal Vslope). In another embodiment, the slope signal Vslope ramps down from the intermediate voltage level V2 to the low voltage level V1 within a fourth period A4 with the negative slope according to the first current source CS1 (as represented by the dashed portion of the slope signal Vslope). In some embodiments, the first period A1, the second period A2, the third period A3, and the fourth period A4 are sequentially performed.

In some embodiments, referring to FIG. 1, the slope signal generator circuit 110 includes a first current source CS1, an output terminal Out, a first switch SW1, and a second switch SW2. In some embodiments, the first current source CS1 may be implemented by a transistor. The first switch SW1 includes a first terminal (e.g., upper terminal) and a second terminal (e.g., lower terminal). The first terminal (e.g., upper terminal) of the first switch SW1 is coupled to the first current source CS1. The second terminal (e.g., lower terminal) of the first switch SW1 is coupled to the output terminal Out. The second switch SW2 includes a first terminal (e.g., upper terminal) and a second terminal (e.g., lower terminal). The first terminal (e.g., upper terminal) of the second switch SW2 is coupled to the output terminal Out. The second terminal (e.g., lower terminal) of the second switch SW2 is configured to receive the low voltage level V1 as shown in FIG. 3. The first switch SW1 and the second switch SW2 are configured to output the slope signal Vslope according to a first control signal Scon1 and a reset signal Sre. In some embodiments, timing diagrams of the first control signal Scon1 and the reset signal Sre are illustrated in FIG. 1. However, the present disclosure is not limited to the above embodiments, which are merely configured to illustratively describe one possible implementation of the present disclosure. Other suitable circuit architectures and timings may also be adopted depending on actual requirements.

In some embodiments, referring to FIG. 1, the slope signal generator circuit 110 includes a second current source CS2 and a third switch SW3. In some embodiments, the second current source CS2 may be implemented by a transistor. The third switch SW3 includes a first terminal (e.g., upper terminal) and a second terminal (e.g., lower terminal). The first terminal (e.g., upper terminal) of the third switch SW3 is coupled to the second current source CS2. The second terminal (e.g., lower terminal) of the third switch SW3 is coupled to the output terminal Out. The third switch SW3 outputs the slope signal Vslope according to a second control signal Scon2. In some embodiments, a timing diagram of the second control signal Scon2 is illustrated in FIG. 1. However, the present disclosure is not limited to the above embodiments, which are merely configured to illustratively describe one possible implementation of the present disclosure. Other suitable circuit architectures and timings may also be adopted depending on actual requirements.

In some embodiments, referring to FIG. 3, the first sub-voltage range Vr1 and the second sub-voltage range Vr2 do not overlap. For example, the first sub-voltage range Vr1 includes a low voltage level V1 and an intermediate voltage level V2. In addition, the second sub-voltage range Vr2 includes the intermediate voltage level V2 and a high voltage level V3. In this embodiment, an upper voltage level of the first sub-voltage range Vr1 (e.g., the intermediate voltage level V2) is the same as a lower voltage level of the second sub-voltage range Vr2 (e.g., the intermediate voltage level V2). Therefore, the first sub-voltage range Vr1 and the second sub-voltage range Vr2 do not overlap. For example, the intermediate voltage level V2 may be selected as an intermediate value between the low voltage level V1 and the high voltage level V3, and the voltage level V2 may be calculated by the following formula:

$$V 2 = \frac{V 1 + V 3}{2} \qquad formula 2$$

However, the intermediate voltage level V2 of the present disclosure is not limited to the above embodiment, and other suitable values may be adopted depending on actual requirements.

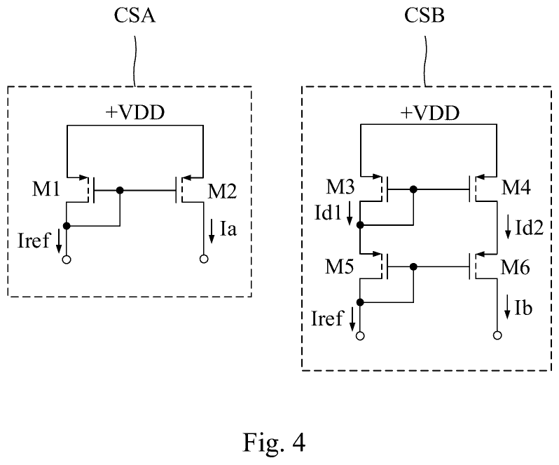

FIG. 4 shows an embodiment of a current source of the slope signal generator circuit 110 shown in FIG. 1 of the present disclosure. The current sources CS1, CS2 of the slope signal generator circuit 110 in FIG. 1 may be implemented by Metal-Oxide-Semiconductor Field-Effect Transistors (MOSFETs). For example, referring to FIG. 4, the current source CS1 or the current source CS2 of the slope signal generator circuit 110 may be a current source CSA implemented by MOSFETs M1, M2. Alternatively, the current source CS1 or the current source CS2 of the slope signal generator circuit 110 may be a current source CSB implemented by MOSFETs M3˜M6. In some embodiments, the slope signal Vslope of the present disclosure is not limited to a rising slope or a falling slope. If the slope signal Vslope is a falling slope, a current source may be implemented by an NMOS (N-type MOSFET).

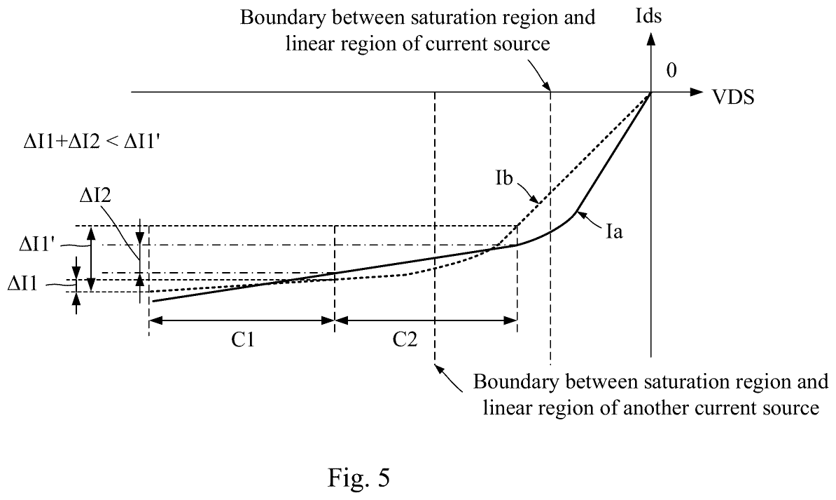

FIG. 5 shows an embodiment of current-voltage characteristic diagram of the slope signal generator circuit 110 shown in FIG. 1 of the present disclosure. As shown in the figure, if only a single current source is utilized, the current Ib may generate a current variation ΔI1′ due to the change in VDS (drain-to-source voltage). In addition, if the period is divided into a period C1 and a period C2, the period C1 is associated with a current variation ΔI1 generated by one current source, and the period C2 is associated with a current variation ΔI2 generated by another current source. As shown in the figure, the total current variation generated by the two current sources is equal to the current variation ΔI1 plus the current variation ΔI2. This total current variation (ΔI1+ΔI2) is less than the current variation ΔI1′ generated by a single current source. Accordingly, the analog to digital conversion device 100 of the present disclosure is configured to reduce the above current variation by utilizing two current sources, thereby improving the nonlinearity of the current source of the slope signal generator circuit 110.

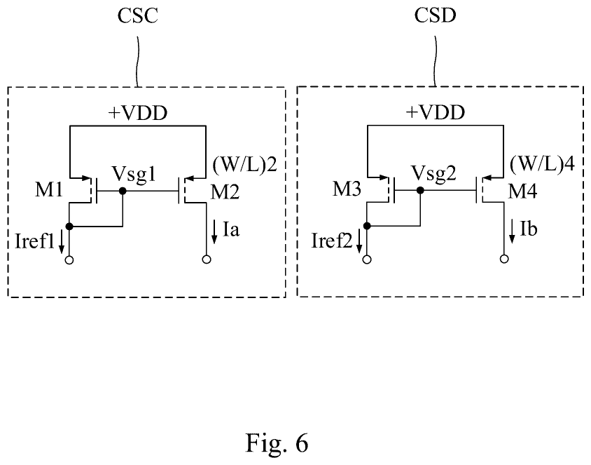

For example, the current Ib shown in FIG. 5 may be provided by the current source CSB of FIG. 4. The current source CSB is a cascode current source that requires a larger |VDS| to operate in a saturation region and has a relatively smaller channel length modulation effect, resulting in a gentler slope. The current Ia shown in FIG. 5 may be provided by the current source CSA of FIG. 4. The current source CSA is a simple current source that exhibits a more significant channel length modulation effect, resulting in a steeper slope, but it requires a smaller |VDS| to operate in a saturation region. Additionally, the currents Ia, Ib in FIG. 5 may also be provided by the current sources CSC, CSD shown in FIG. 6. The present disclosure may design the MOSFETs M2, M4 of the current sources CSC and CSD, respectively, to have different Vsg (source-gate voltage) and different W/L (width-to-length ratio) to provide the currents Ia, Ib, wherein Vsg1 of the current source CSC is not equal to Vsg2 of the current source CSD, and (W/L)2 of the current source CSC is not equal to (W/L)4 of the current source CSD.

It should be noted that the present disclosure is not limited to the embodiments as shown in FIG. 1 to FIG. 6, they are merely examples for illustrating the implements of the present disclosure, and the scope of the present disclosure shall be defined based on the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

Technical features of some embodiments of the present disclosure make an improvement to the prior art. The analog to digital conversion device and the analog to digital conversion method of the present disclosure can improve nonlinearity of current sources of slope signal generator circuits.

It should be noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An analog to digital conversion device, comprising:
a slope signal generator circuit, configured to generate a slope signal within a first sub-voltage range of a voltage range according to a first current source, and generate the slope signal within a second sub-voltage range of the voltage range according to a second current source, wherein the slope signal repeatedly ramps up and down within the voltage range with at least one slope; and
a comparator circuit, configured to generate an output signal according to the slope signal and an input signal.

2. The analog to digital conversion device of claim 1, wherein the voltage range comprises a low voltage level and a high voltage level, and the at least one slope comprises a positive slope and a negative slope, wherein the slope signal ramps up from the low voltage level to the high voltage level with the positive slope, and then ramps down from the high voltage level to the low voltage level with the negative slope.

3. The analog to digital conversion device of claim 2, wherein the slope signal generator circuit comprises the first current source, the first current source comprises at least one first transistor, and the slope signal generator circuit further comprises:
an output terminal;
a first switch, comprising:
a first terminal, coupled to the first current source; and
a second terminal, coupled to the output terminal; and
a second switch, comprising:
a first terminal, coupled to the output terminal; and
a second terminal, configured to receive the low voltage level;
wherein the first switch and the second switch output the slope signal according to a first control signal and a reset signal.

4. The analog to digital conversion device of claim 3, wherein the slope signal generator circuit comprises the second current source, the second current source comprises at least one second transistor, and the slope signal generator circuit further comprises:
a third switch, comprising:
a first terminal, coupled to the second current source; and
a second terminal, coupled to the output terminal;
wherein the third switch outputs the slope signal according to a second control signal.

5. The analog to digital conversion device of claim 1, wherein the first sub-voltage range comprises a low voltage level, a boundary between the first sub-voltage range and the second sub-voltage range comprises an intermediate voltage level, and the at least one slope comprises a positive slope and a negative slope, wherein the slope signal ramps up from the low voltage level to the intermediate voltage level within a first period with the positive slope according to the first current source.

6. The analog to digital conversion device of claim 5, wherein the second sub-voltage range comprises a high voltage level, wherein the slope signal ramps up from the intermediate voltage level to the high voltage level within a second period with the positive slope according to the second current source.

7. The analog to digital conversion device of claim 6, wherein the slope signal ramps down from the high voltage level to the intermediate voltage level within a third period with the negative slope according to the second current source.

8. The analog to digital conversion device of claim 7, wherein the slope signal ramps down from the intermediate voltage level to the low voltage level within a fourth period with the negative slope according to the first current source.

9. The analog to digital conversion device of claim 8, wherein the first period, the second period, the third period, and the fourth period are sequentially performed.

10. The analog to digital conversion device of claim 1, wherein the first sub-voltage range and the second sub-voltage range do not overlap.

11. An analog to digital conversion method, comprising:
generating a slope signal within a first sub-voltage range of a voltage range according to a first current source, and generating the slope signal within a second sub-voltage range of the voltage range according to a second current source by a slope signal generator circuit, wherein the slope signal repeatedly ramps up and down within the voltage range with at least one slope; and
generating an output signal according to the slope signal and an input signal by a comparator circuit.

12. The analog to digital conversion method of claim 11, wherein the voltage range comprises a low voltage level and a high voltage level, and the at least one slope comprises a positive slope and a negative slope, wherein the slope signal ramps up from the low voltage level to the high voltage level with the positive slope, and then ramps down from the high voltage level to the low voltage level with the negative slope.

13. The analog to digital conversion method of claim 12, wherein the slope signal generator circuit comprises the first current source, an output terminal, a first switch, and a second switch, wherein the first current source comprises at least one first transistor, wherein a first terminal of the first switch is coupled to the first current source, and a second terminal of the first switch is coupled to the output terminal, wherein a first terminal of the second switch is coupled to the output terminal, and a second terminal of the second switch is configured to receive the low voltage level, wherein generating the slope signal within the first sub-voltage range of the voltage range according to the first current source by the slope signal generator circuit comprises:
outputting the slope signal within the first sub-voltage range of the voltage range according to a first control signal and a reset signal by the first switch and the second switch of the slope signal generator circuit.

14. The analog to digital conversion method of claim 13, wherein the slope signal generator circuit further comprises the second current source and a third switch, wherein the second current source comprises at least one second transistor, wherein a first terminal of the third switch is coupled to the second current source, and a second terminal of the third switch is coupled to the output terminal, wherein generating the slope signal within the second sub-voltage range of the voltage range according to the second current source by the slope signal generator circuit comprises:
outputting the slope signal within the second sub-voltage range of the voltage range according to the reset signal and a second control signal by the second switch and the third switch of the slope signal generator circuit.

15. The analog to digital conversion method of claim 11, wherein the first sub-voltage range comprises a low voltage level, a boundary between the first sub-voltage range and the second sub-voltage range comprises an intermediate voltage level, and the at least one slope comprises a positive slope and a negative slope, wherein the slope signal ramps up from the low voltage level to the intermediate voltage level within a first period with the positive slope according to the first current source.

16. The analog to digital conversion method of claim 15, wherein the second sub-voltage range comprises a high voltage level, wherein the slope signal ramps up from the intermediate voltage level to the high voltage level within a second period with the positive slope according to the second current source.

17. The analog to digital conversion method of claim 16, wherein the slope signal ramps down from the high voltage level to the intermediate voltage level within a third period with the negative slope according to the second current source.

18. The analog to digital conversion method of claim 17, wherein the slope signal ramps down from the intermediate voltage level to the low voltage level within a fourth period with the negative slope according to the first current source.

19. The analog to digital conversion method of claim 18, wherein the first period, the second period, the third period, and the fourth period are sequentially performed.

20. The analog to digital conversion method of claim 11, wherein the first sub-voltage range and the second sub-voltage range do not overlap.
